(19) United States
(12) Patent Application Publication
(10) Pub. No.: US 2012/0061642 A1
(43) Pub. Date: Mar. 15, 2012

(54) SEMICONDUCTOR LIGHT EMITTING DEVICE AND MANUFACTURING METHOD THEREOF

(75) Inventor: Satoshi TANAKA, Tokyo (JP)

(73) Assignee: STANLEY ELECTRIC CO., LTD., Tokyo (JP)

(21) Appl. No.: 13/246,415

(22) Filed: Sep. 27, 2011

(30) Foreign Application Priority Data
Sep. 13, 2010 (JP) 2010-215194

(51) Int. Cl. H01L 33/04; H01L 33/42

(52) U.S. Cl. 257/13; 438/47; 257/E33.003; 257/E33.064

(57) ABSTRACT

A semiconductor light emitting device which includes an n-type semiconductor layer, a p-type semiconductor layer, and an active layer provided between the n-type semiconductor layer and the p-type semiconductor layer. The semiconductor light emitting device comprises a first transparent electrode made of metal oxide transparent conductor provided on a surface of the p-type semiconductor layer; a second transparent electrode made of a metal oxide transparent conductor provided on the surface of the p-type semiconductor layer and electrically connected to the first transparent electrode; and a p-side electrode pad made of metal provided on a surface of the second transparent electrode. The second transparent electrode is higher in contact resistance with the p-type semiconductor layer than the first transparent electrode.

### BACKGROUND OF THE INVENTION

1. Field of the Invention

The present invention relates to a semiconductor light emitting device such as a light emitting diode (LED) and particularly to a structure for controlling current spreading inside a semiconductor layer.

2. Description of the Related Art

So-called face-up type semiconductor light emitting devices are manufactured by sequentially laying an n-type semiconductor layer, an active layer, and a p-type semiconductor layer one over another on a insulating growth substrate and removing parts of the p-type semiconductor layer and of the active layer to expose the n-type semiconductor layer partially and forming a p-side electrode and an n-side electrode respectively on the surface of the p-type semiconductor layer and the exposed surface of the n-type semiconductor layer. The p-side electrode is formed by laying an electrode pad made of metal on a transparent electrode made of tin-doped indium oxide (ITO: Indium Tin Oxide) or the like widely covering the surface of the p-type semiconductor layer.

However, according to the above-mentioned electrode configuration, because current supplied via the p-side electrode pad flows through the shortest path toward the n-side electrode, current spreading in the semiconductor layers is not sufficient, resulting in an increase in the forward voltage and a reduction in luminous efficiency. Further, Joule heat is increased immediately beneath the p-side electrode pad on which current is concentrated. Thus p-side electrode pad may peel from the transparent electrode due to thermal stress generated at the interface between the p-side electrode pad and the transparent electrode.

As to a technique of suppressing the current concentration immediately beneath the p-side electrode pad, for example, Reference 1 (Japanese Patent Application Laid-Open Publication No. H10-294531) discloses a semiconductor light emitting device having a current blocking layer made of TiO₂ inside a p-type GaN layer.

Reference 2 (Japanese Patent Application Laid-Open Publication No. H10-173224) discloses a semiconductor light emitting device including a SiO₂ film and an ITO transparent electrode arranged on a surface of a p-type GaN layer, and a p-side electrode pad formed on the SiO₂ film so as to come in contact with part of the ITO transparent electrode.

Reference 3 (Japanese Patent Application Laid-Open Publication No. 2006-156590) discloses a semiconductor light emitting device wherein a current blocking layer made of Ag or the like relatively large in contact resistance with an n-type GaN layer and a transparent electrode made of ITO relatively small in contact resistance with the n-type GaN layer are formed on a surface of the n-type GaN layer that is the outermost semiconductor layer and wherein an electrode pad is formed immediately above the current blocking layer.

### SUMMARY OF THE INVENTION

In case where a current blocking layer of TiO₂ is formed inside a p-type GaN layer, as described in Reference 1, the following process is needed. After the p-type GaN layer is formed, the temperature inside an MOCVD apparatus is lowered to room temperature to take out the wafer. The wafer is placed in the chamber of a vacuum evaporation apparatus, and a Ti is deposited on the wafer. The Ti film is patterned by photolithography and etching. The wafer is placed in an oxidation furnace to oxidize the Ti film into a TiO₂ film. The wafer is placed in the MOCVD apparatus again to perform crystal growth. As such, in order to form a TiO₂ film inside a semiconductor layer, the crystal growth process is interrupted, resulting in the process being complicated. Further, because the wafer is handled with the crystal growth process being interrupted, a decrease in yield is caused, thus increasing production cost.

In case where a p-side electrode pad is formed on the SiO₂ film so as to come in contact with part of the ITO transparent electrode, as described in Reference 2, current concentrates on the junction between the p-side electrode pad and the ITO transparent electrode. In this case heat is generated at the junction due to current concentration and the p-side electrode pad may peel from the transparent electrode due to thermal stress. Hence, this electrode configuration is a factor to reduce reliability. Meanwhile, in order to improve light extraction efficiency, the p-side electrode pad needs to be formed as small as possible, and hence it is difficult to enlarge the area of the junction between the p-side electrode pad and the ITO transparent electrode. Thus, when a large current is supplied, the current concentrates on the junction between the p-side electrode pad and the ITO transparent electrode, resulting in an increase in the forward voltage.

In case where an outermost semiconductor layer is an n-type GaN layer, as described in Reference 3, heat when the n-type GaN layer is being formed, degrades the active layer, resulting in a decrease in internal quantum efficiency. Further, the outermost n-type GaN layer is contaminated in the photolithography for patterning the current blocking layer, which makes it difficult to form good ohmic contact between a transparent electrode formed later and the n-type GaN layer. Yet further, where the current blocking layer is formed of metal, even if the metal has a high reflectance, part of light emitted from the active layer is absorbed by the current blocking layer, thus reducing light extraction efficiency.

The present invention was conceived in view of the above facts, and an object thereof is to provide a semiconductor light emitting device which can be manufactured by a relatively simple and easy way to solve the conventional problems of a decrease in yield, a reduction in reliability, an increase in drive voltage, and a decrease in light extraction efficiency, and to provide a manufacturing method thereof.

According to the present invention, there is provided a semiconductor light emitting device which includes an n-type semiconductor layer, a p-type semiconductor layer, and an active layer provided between the n-type semiconductor layer and the p-type semiconductor layer. The semiconductor light emitting device comprises a first transparent electrode made of a metal oxide transparent conductor provided on a surface of the p-type semiconductor layer; a second transparent electrode made of a metal oxide transparent conductor provided on the surface of the p-type semiconductor layer and electrically connected to the first transparent electrode; and a p-side electrode pad made of metal provided on a surface of the second transparent electrode. The second transparent electrode is higher in contact resistance with the p-type semiconductor layer than the first transparent electrode.

Further, a manufacturing method of a semiconductor light emitting device according to the present invention, comprises the steps of forming sequentially an n-type semiconductor layer, an active layer, and a p-type semiconductor layer on a surface of a growth substrate; forming a metal oxide transparent conductive film on a surface of the p-type semiconductor layer; sintering the metal oxide transparent conductive film by heat treatment to form a first transparent electrode; forming a metal oxide transparent conductive film so as to come in contact with the first transparent electrode on the surface of the p-type semiconductor layer to form a second transparent electrode; and forming a p-side electrode pad made of metal on a surface of the second transparent electrode.

According to the semiconductor light emitting device and its manufacturing method of the present invention, the light emitting device can be manufactured by a relatively simple and easy way. Further, it is possible to provide the semiconductor light emitting device and its manufacturing method which can solve the conventional problems such as a decrease in manufacturing yield, a reduction in reliability, an increase in drive voltage, and a decrease in light extraction efficiency.

### BRIEF DESCRIPTION OF THE DRAWINGS

FIG. 1A is a plan view showing the configuration of a semiconductor light emitting device according to Embodiment 1 of the present invention;

FIG. 1B is a cross-sectional view taken along line 1B-1B in FIG. 1A;

FIGS. 2A to 2C are cross-sectional views showing a manufacturing method of the semiconductor light emitting device according to the embodiment of the present invention;

FIGS. 3A and 3B are cross-sectional views showing the manufacturing method of the semiconductor light emitting device according to the embodiment of the present invention;

FIG. 4 shows the transmittance spectra of a first transparent electrode and a second transparent electrode according to the embodiment of the present invention;

FIG. 5A is a plan view showing the configuration of a semiconductor light emitting device according to Embodiment 2 of the present invention;

FIG. 5B is a cross-sectional view taken along line 5B-5B in FIG. 5A; and

FIG. 6 is a cross-sectional view showing the configuration of a semiconductor light emitting device according to Embodiment 3 of the present invention.

### DETAILED DESCRIPTION OF THE INVENTION

Embodiments of the present invention will be described below with reference to the drawings. In the figures cited below, the same reference numerals are used to denote substantially the same or equivalent constituents or parts.

### Embodiment 1

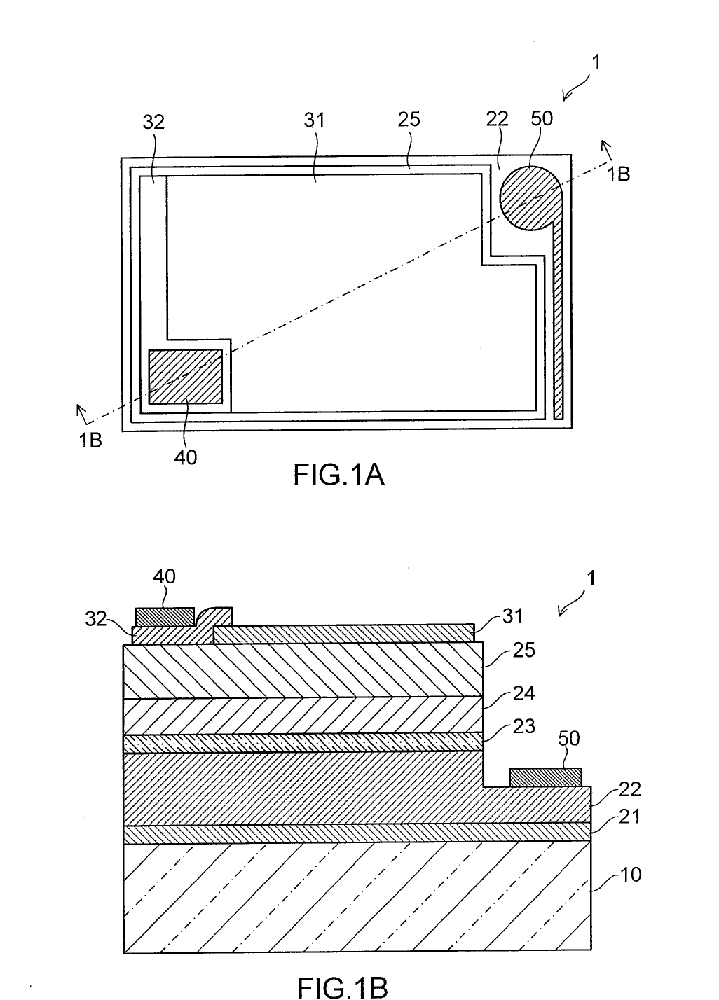

FIG. 1A is a plan view of a semiconductor light emitting device 1 according to Embodiment 1 of the present invention, and FIG. 1B is a cross-sectional view taken along line 1B-1B in FIG. 1A.

A growth substrate 10 is a substrate for crystal-growing a GaN-based semiconductor film on and is, for example, a C-plane sapphire substrate. A GaN-based nitride semiconductor layer represented by AlₓIn_{y}Ga_{1-x-y}N (0≦x≦1, 0≦y≦1) is formed on the growth substrate 10. The nitride semiconductor layer is configured with a buffer layer 21, an n-type contact layer 22, an active layer 23, a p-type clad layer 24, and a p-type contact layer 25 that are laid one over another in that order. The n-type contact layer 22 has a predetermined concentration of Si doped therein to have n-type conductivity. The p-type clad layer 24 and the p-type contact layer 25 have a predetermined concentration of Mg doped therein to have p-type conductivity. The active layer 23 has a multi-quantum well structure where, e.g., InGaN well layers and GaN barrier layers are laid one over the other repeatedly. Note that the layered structure of the nitride semiconductor layer can be any of a homo-junction structure, a single hetero-junction structure, and a double hetero-junction structure.

The semiconductor light emitting device 1 is a so-called face-up type semiconductor light emitting device, and part of the n-type contact layer 22 is exposed on the same side as is the p-type contact layer 25. An n-side electrode pad 50 configured with Ti and Al laid one over the other in that order is provided on the exposed surface of the n-type contact layer 22. The n-side electrode pad 50 forms ohmic contact with the n-type contact layer 22.

On the surface of the p-type contact layer 25, there are formed a first transparent electrode 31 of about 110 nm thickness made of, e.g., tin-doped indium oxide (ITO: Indium Tin Oxide) and a second transparent electrode 32 of about 110 nm thickness also made of tin-doped indium oxide. The first transparent electrode 31 and the second transparent electrode 32 need not be completely transparent, but need only have transparency or transmissivity to light from the active layer 23. Also, the first transparent electrode 31 and the second transparent electrode 32 have conductivity. The second transparent electrode 32 is formed so as to partially overlap the first transparent electrode 31, and these are electrically connected to each other. The first transparent electrode 31 and the second transparent electrode 32 are different from each other in contact resistance with the p-type contact layer 25. That is, contact resistance between the first transparent electrode 31 and the p-type contact layer 25 is, for example, 2×10⁻⁴ Ωcm² to 7×10⁻³ Ωcm², while contact resistance between the second transparent electrode 32 and the p-type contact layer 25 is, for example, 20 Ωcm² or greater. That is, the second transparent electrode 32 has contact resistance 1,000 times or more greater than that of the first transparent electrode 31. The sheet resistance of the first transparent electrode 31 is, for example, 100 to 200Ω/□, while the sheet resistance of the second transparent electrode 32 is, for example, 10 to 40Ω/□. These differences in electrical characteristics between the first transparent electrode 31 and the second transparent electrode 32 are brought about by the presence/absence of sintering the ITO film forming the transparent electrodes after the ITO deposition, the details of which will be described later.

On the surface of the second transparent electrode 32, there are formed a p-side electrode pad 40 configured with Ni and Au laid one over the other in that order. The p-side electrode pad 40 comes in contact with only the second transparent electrode 32, not with the first transparent electrode 31.

The n-side electrode pad 50 and the p-side electrode pad 40 are respectively placed near opposite corners of the semiconductor light emitting device 1 having a rectangular shape. Current supplied via the p-side electrode pad 40 flows into the second transparent electrode 32. Because, as mentioned above, the contact resistances of the first transparent electrode 31 and the second transparent electrode 32 with the p-type contact layer 25 are remarkably different, the current spreads over the entire area of the first transparent electrode 31 having low contact resistance and is injected mainly from the first transparent electrode 31 into the p-type contact layer 25 to flow toward the n-side electrode pad 50. Meanwhile, almost no current is injected from the second transparent electrode 32 having high contact resistance with the p-type contact layer 25 into the p-type contact layer 25. That is, the second transparent electrode 32 diverts the supplied current to the first transparent electrode 31, thus serving as a current control layer that suppresses current concentration immediately beneath the p-side electrode pad 40. The current distribution inside the nitride semiconductor layer can be made uniform by appropriately setting the arrangement and areas of the first and second transparent electrodes. If a transparent electrode on the surface of the p-type contact layer 25 were formed of only the first transparent electrode 31 having low contact resistance, current would be concentrated in a path extending through immediately beneath the p-side electrode pad 40, resulting in a non-uniform luminance distribution, an increase in the forward voltage, and a reduction in reliability.

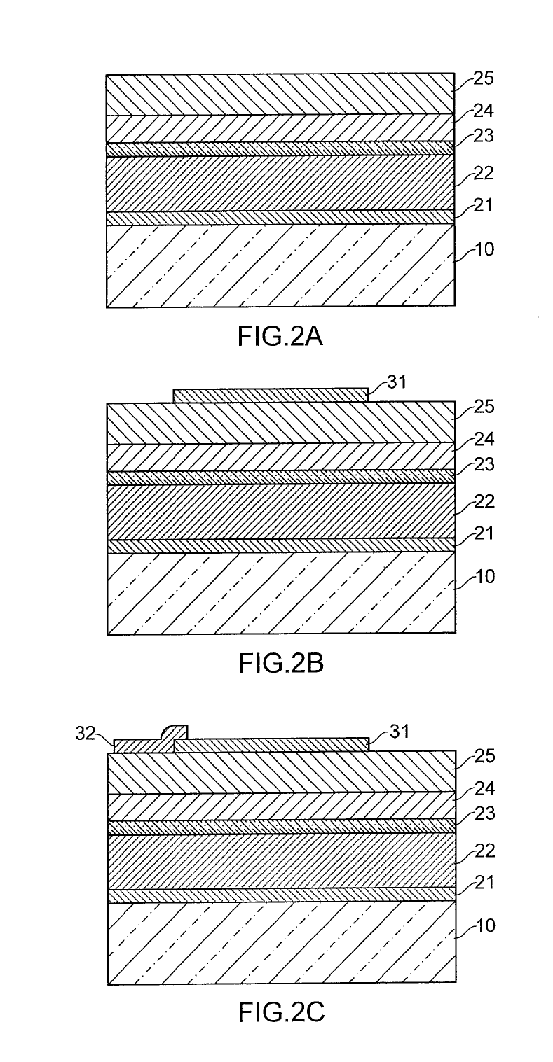

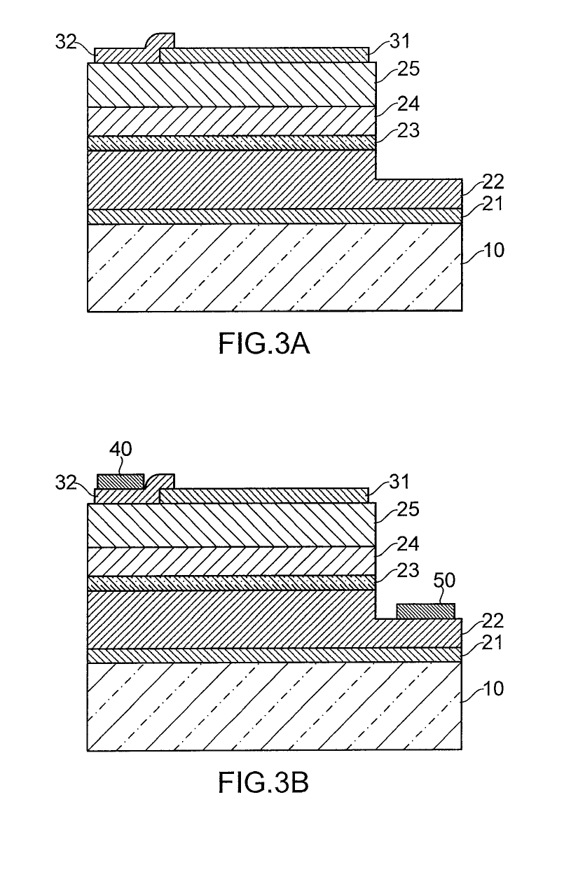

Next, the manufacturing method of the semiconductor light emitting device 1 having the above configuration will be described. FIGS. 2A to 2C and FIGS. 3A, 3B are cross-sectional views showing process steps in the production process of the semiconductor light emitting device 1.

### (Nitride Semiconductor Layer Forming Process)

First, the growth substrate 10 is prepared. In the present embodiment, a C-plane sapphire substrate is used as the growth substrate on which a GaN-based nitride semiconductor layer can be formed by a metal organic chemical vapor deposition (MOCVD) method.

The growth substrate 10 is placed in an MOCVD apparatus and is heated in a hydrogen atmosphere of about 1,000° C. for about 10 minutes (thermal cleaning). Then, the substrate temperature is adjusted to about 500° C., and trimethylgallium (TMG) (flow rate: 10.4 μmol/min) and ammonia (NH₃) (flow rate: 3.3 LM) are supplied for 3 minutes, thereby forming the n-type buffer layer 21 made of GaN. Then, the substrate temperature is raised to 1,000° C. and maintained for 30 seconds to crystallize the n-type buffer layer.

Then, at a substrate temperature (or growth temperature) of 1,000° C., trimethylgallium (TMG) (flow rate: 45 μmol/min), ammonia (NH₃) (flow rate: 4.4 LM), and silane (SiH₄) (flow rate: 2.7×10⁻⁹ μmmol/min) are supplied for 60 minutes, thereby forming the n-type contact layer 22 made of GaN of about 4 μm thickness.

A multi-quantum well structure of InGaN/GaN is applied to the active layer 23. In the present embodiment, with an InGaN well layer/GaN barrier layer as a period, five periods of growth is performed. At substrate temperature of about 700° C., trimethylgallium (TMG) (flow rate: 3.6 μmol/min), trimethylindium (TMI) (flow rate: 10 μmol/min), and ammonia (NH₃) (flow rate: 4.4 LM) are supplied for 33 seconds, thereby forming an InGaN well layer of about 2.2 nm thickness. Subsequently, trimethylgallium (TMG) (flow rate: 3.6 μmol/min) and ammonia (NH₃) (flow rate: 4.4 LM) are supplied for 320 seconds, thereby forming a GaN barrier layer of about 15 nm thickness. By repeating this process five periods, the active layer 23 is formed.

Then, the substrate temperature is raised to 870° C., and trimethylgallium (TMG) (flow rate: 8.1 μmol/min), trimethylaluminum (TMA) (flow rate: 7.5 μmol/min), ammonia (NH₃) (flow rate: 4.4 LM), and Cp₂Mg (bis-cyclopentadienyl Mg) (flow rate: 2.9×10⁻⁷ μmol/min) are supplied for 5 minutes, thereby forming the p-type clad layer 24 made of AlGaN of about 40 nm thickness. Subsequently, with the temperature maintained, trimethylgallium (TMG) (flow rate: 18 μmol/min), ammonia (NH₃) (flow rate: 4.4 LM), and Cp₂Mg (flow rate: 2.9×10⁻⁷ μmol/min) are supplied for 7 minutes, thereby forming the p-type contact layer 25 made of GaN of about 150 nm thickness (FIG. 2A).

### (P-Type Contact Layer Activating Process)

The wafer is taken out of the MOCVD apparatus, and the p-type contact layer 25 is activated. In the growth process, hydrogen that is a material of a carrier gas is mixed in the p-type contact layer 25 to form Mg—H bonds. In this state, the doped Mg cannot serve as a dopant, and thus the p-type contact layer 25 has high resistance. Hence, an activating process of degassing hydrogen mixed in the p-type contact layer 25 is necessary. Specifically, heat treatment is performed on the wafer in an inert gas atmosphere of 400° C. or higher to activate the p-type contact layer 25.

### (First Transparent Electrode Forming Process)

The first transparent electrode 31 is formed on the surface of the activated p-type contact layer 25. With the substrate temperature being about 200° C., an ITO film of about 110 nm thickness is formed on the surface of the p-type contact layer 25 by an RF sputtering method. Then, a resist mask having a predetermined opening pattern is formed on the ITO film, and the ITO film is wet etched through the openings of the resist mask to pattern the ITO film. Note that the substrate temperature when forming the ITO film can be set to be 150° C. or higher but not higher than 300° C. The crystallization of the ITO is promoted at a substrate temperature of 150° C. or higher. The situation where the crystallization is not promoted because of a low substrate temperature is not preferable because the optical transmittance of the ITO is greatly reduced. Meanwhile, if the substrate temperature is 300° C. or higher, the crystallization is promoted, thus making etching for patterning the ITO film difficult. Further, in this case, because the amount of oxygen in the ITO film increases, oxygen vacancies decrease in number to decrease the carrier concentration, resulting in an increase in sheet resistance, which is not preferable.

After removing the resist mask, the wafer is placed in an atmosphere of 600° C. containing oxygen and is heat treated for one minute. By this heat treatment, the sintering of the ITO film is performed, thereby greatly reducing the contact resistance between the ITO film and the p-type contact layer 25. Also, by this heat treatment, oxygen is introduced in oxygen vacancy sites in the ITO film, thus improving crystallinity. That is, the crystallization promotion and the sintering of the ITO film are performed simultaneously by this heat treatment. The heat treatment temperature for the ITO film is preferably set to be in the range of 500 to 700° C. If the heat treatment temperature is 400° C. or lower, the sintering of the ITO film is not promoted, and thus the contact resistance with the p-type contact layer 25 cannot be lowered sufficiently. In contrast, if the heat treatment temperature is 800° C. or higher, the nitrogen outgassing from the p-type contact layer 25 will occur. Hence this is not preferable. Having undergone the above steps, the first transparent electrode 31 is formed on the p-type contact layer 25 (FIG. 2B).

### (Second Transparent Electrode Forming Process)

The second transparent electrode 32 is formed on the surface of the p-type contact layer 25 so as to be electrically connected to the first transparent electrode 31. With the substrate temperature being about 200° C., an ITO film of about 110 nm thickness is formed on the surface of the p-type contact layer 25 having the first transparent electrode 31 formed thereon by the RF sputtering method such that the ITO film covers also the surface of the first transparent electrode 31 formed in the preceding process. Note that the substrate temperature when forming the ITO film can be set to be 150° C. or higher but not higher than 300° C. Then, a resist mask having a predetermined opening pattern is formed on the ITO film, and the ITO film is wet etched through the openings of the resist mask to pattern the ITO film. This etching makes the surface of the first transparent electrode 31 exposed. Patterning is performed such that an end portion of the second transparent electrode 32 overlaps with the first transparent electrode 31. Note that since its crystallization was promoted by the previous heat treatment in the oxygen atmosphere, the first transparent electrode 31 is very low in etching rate and hence is not removed in this etching step. For the ITO film forming the second transparent electrode 32, heat treatment after ITO deposition is not performed. That is, the sintering of the second transparent electrode 32 is not performed, and the state of interface between the ITO film and the p-type contact layer immediately after ITO deposition is maintained. Thus, contact resistance with the p-type contact layer 25 of the second transparent electrode 32 is higher than that of the first transparent electrode 31. Having undergone the above steps, the second transparent electrode 32 is formed on the p-type contact layer 25 (FIG. 2C).

### (N-Type Contact Layer Exposing Process)

The Nitride Semiconductor Layer is Etched from the p-type contact layer 25 side to make the n-type contact layer 22 partially exposed. A resist mask (not shown) is formed which covers a predetermined area of the p-type contact layer 25, which area includes the region where the first and second transparent electrodes are formed. Then, the wafer is placed in a reactive ion etching (RIE) apparatus, and the nitride semiconductor layer continues to be etched from the p-type contact layer 25 side until the n-type contact layer 22 is exposed (FIG. 3A).

### (N-Side Electrode Pad Forming Process)

The N-Side Electrode Pad 50 is Formed on the exposed surface of the n-type contact layer 22. After a resist mask (not shown) having an opening on the region where the n-side electrode pad is to be formed, is formed on the surface of the n-type contact layer 22, Ti (1 nA) and Al (1 μm) are deposited in that order by EB vapor deposition. Then, the n-side electrode pad 50 is patterned with a lift-off technology.

### (P-Side Electrode Pad Forming Process)

The p-side electrode pad 40 is formed on the surface of the second transparent electrode 32. After a resist mask (not shown) having an opening on the region where the p-side electrode pad is to be formed, is formed on the surface of the second transparent electrode 32, Ni (25 nA) and Au (500 nm) are deposited in that order by EB vapor deposition. Then, the p-side electrode pad 40 is patterned with a lift-off technology. The p-side electrode pad 40 is formed covering part of the surface of the second transparent electrode 32, without coming in contact with the first transparent electrode 31. Note that a layer of Ag, Pt, Al, or an alloy containing any of these, having a high reflectance may be inserted between the Ni layer and the Au layer (FIG. 3B).

By undergoing the above steps, the semiconductor light emitting device 1 is completed. Evaluation results of various characteristics of the first transparent electrode 31 and the second transparent electrode 32 of the semiconductor light emitting device produced by the above manufacturing method will be shown below.

Measured values of the sheet resistance and the contact resistance with the p-type contact layer 25 of the first transparent electrode 31 and the second transparent electrode 32 are shown in Table 1. Regarding the contact resistance of the first transparent electrode 31 with the p-type contact layer 25, a low enough resistance value for the first transparent electrode 31 to serve as an ohmic electrode was obtained. Regarding the contact resistance of the second transparent electrode 32 with the p-type contact layer 25, a suitable resistance value for the second transparent electrode 32 to serve as a current control layer was obtained. That is, a remarkable difference in contact resistance between the first transparent electrode 31 and the second transparent electrode 32 was obtained. The difference in contact resistance between first and second transparent electrode was caused by the presence/absence of ITO sintering process. Specifically, while for the first transparent electrode 31 the sintering of the ITO film by heat treatment was performed, for the second transparent electrode 32 the sintering of the ITO film was not performed so that the state of interface between the ITO film and the p-type contact layer immediately after ITO deposition was maintained. By providing such a remarkable difference in contact resistance between the first transparent electrode 31 and the second transparent electrode 32, current injection into the p-type contact layer 25 is performed mainly via the first transparent electrode 31. Almost no current flows immediately beneath the second transparent electrode 32. In other words, the second transparent electrode 32 can be made to effectively serve as a current control layer, thus current concentration immediately beneath the p-side electrode pad 40 can be prevented. By this means, the current distribution inside the nitride semiconductor layer can be made uniform, and thus the uniformalization of luminance distribution, a reduction in the forward voltage, and an improvement in reliability can be achieved.

Meanwhile, it was confirmed that sheet resistance of the second transparent electrode 32 was lower than that of the first transparent electrode 31. It can be thought that oxygen was introduced in oxygen vacancy sites of the first transparent electrode 31 by heat treatment after the deposition of the ITO, thus promoting crystallization, resulting in a decrease in carrier density of the first transparent electrode 31. However, its absolute value is tolerable in actual use. In contrast, as to the second transparent electrode 32, because oxygen outgassing occurred at the deposition of the ITO, the number of oxygen vacancy sites was relatively large. Thus the carrier density was relatively high and sheet resistance was relatively low.

As such, the second transparent electrode 32 has an advantageous characteristic to make current flow in a direction parallel to the principal surface of the semiconductor light emitting device 1, and the first transparent electrode 31 has an advantageous characteristic to make current flow in a layer stack direction of the semiconductor light emitting device 1.

TABLE 1

| | first transparent | second transparent |
|---|---|---|
| | electrode | electrode |
| contact resistance | 3.82 × 10⁻³ Ωcm² | 5.13 × 10¹ Ωcm² |
| sheet resistance | 100 Ω/□ | 22.6 Ω/□ |

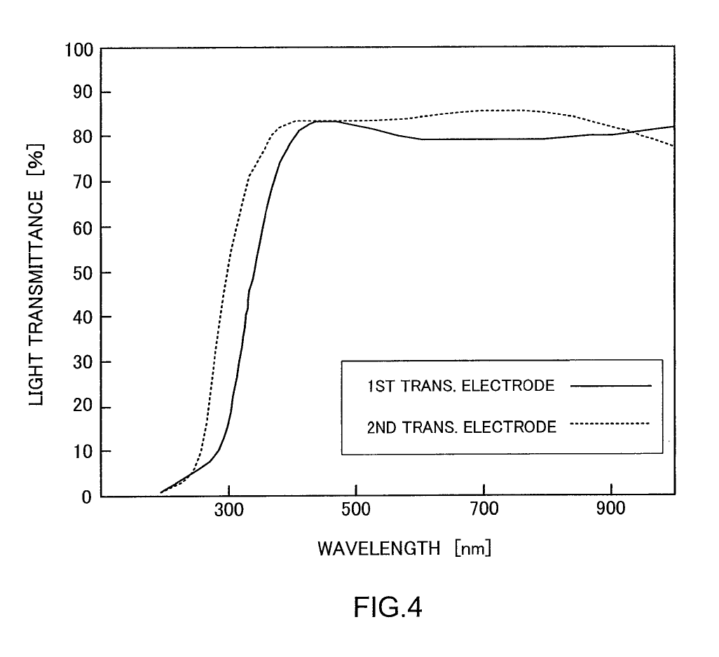

FIG. 4 shows the transmittance spectra of the first transparent electrode 31 and the second transparent electrode 32. It was confirmed that the light absorption end of the second transparent electrode 32 is located at a shorter wavelength than that of the first transparent electrode 31 is. This means that the second transparent electrode 32 has a larger bandgap and higher transparency than the first transparent electrode 31 does. Because the second transparent electrode 32 has higher transparency, the absorption of light passing through the first transparent electrode 31, that is, light emitted from the active layer 23, reflected by the p-side electrode pad 40, and then sent out to the outside can be suppressed, thus improving light extraction efficiency.

As obvious from the above description, according to the semiconductor light emitting device and its manufacturing method of the embodiment of the present invention, the two transparent electrodes remarkably different in their contact resistance with the nitride semiconductor layer are formed on a surface of the nitride semiconductor layer. By this means, the first transparent electrode 31 having relatively low contact resistance with the nitride semiconductor layer serves as an ohmic electrode, while the second transparent electrode 32 having relatively high contact resistance with the nitride semiconductor layer serves as a current control layer. Since the p-side electrode pad 40 is formed so as to come in contact with only the second transparent electrode 32 which serves as a current control layer, current concentration immediately beneath the p-side electrode pad can be prevented. By this means, the electric current distribution inside the nitride semiconductor layer is made uniform, and thus the uniformalization of the luminance distribution, a reduction in the forward voltage, and an improvement in reliability can be achieved.

Further, according to the semiconductor light emitting device and its manufacturing method of the embodiment of the present invention, a current spreading structure is formed by forming the two transparent electrodes different from each other in their contact resistance with the nitride semiconductor layer on the surface of the nitride semiconductor layer, and hence the work of transferring the wafer into another processing apparatus during the growth process of the nitride semiconductor layer is not needed. That is, the semiconductor light emitting device according to the present invention can be easily produced as compared with the conventional method having a step for forming a metal oxide film such as titanium oxide (TiO₂) which constitutes a current constriction structure in the semiconductor layer (see Reference 1). Therefore a reduction in production cost and an improvement in manufacturing yield can be achieved.

Yet further, because second transparent electrode 32 which serves as current control layer is connected to the entire surface of the p-side electrode pad 40, current concentration in the p-side electrode pad can be relaxed as compared with the conventional electrode structure where the current control layer is composed of an insulating film such as a SiO₂ film and the p-side electrode pad partially connects to the ITO transparent electrode (Reference 2). Because an entire junction between second transparent electrode 32 and p-side electrode pad 40 can form a current path, the forward voltage can be reduced and the peeling of the p-side electrode pad due to thermal stress can be prevented.

Moreover, according to the manufacturing method of the semiconductor light emitting device of the embodiment of the present invention, since a process for forming a resist mask on the surface of the nitride semiconductor layer is not performed before the first transparent electrode 31 which serves as an ohmic electrode is formed, the surface of the nitride semiconductor layer is not contaminated. Therefore the desirable electrical connection between the first transparent electrode and the nitride semiconductor layer can be formed. Further, because the current control layer is constituted by a transparent electrode, light incident into the current control layer at angles greater than or equal to the critical angle from the nitride semiconductor layer is entirely reflected by total reflection and sent out to the outside. That is, as compared with the case where the current control layer is formed of a metal having a high reflectance such as Ag, the absorption of light can be reduced, thus improving light extraction efficiency.

### Embodiment 2

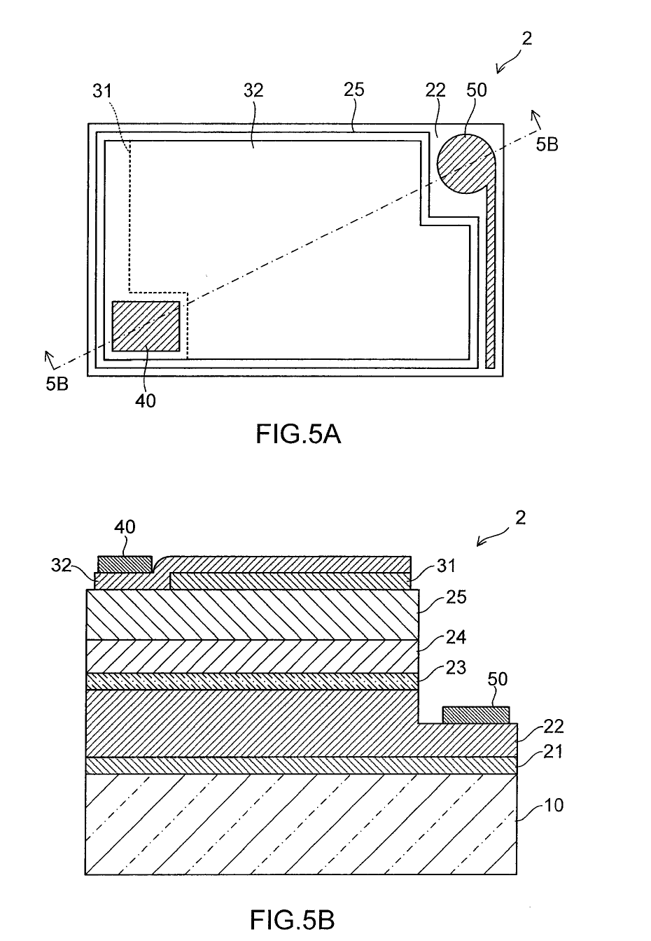

FIG. 5A is a plan view showing the configuration of a semiconductor light emitting device 2 according to Embodiment 2 of the present invention, and FIG. 5B is a cross-sectional view taken along line 5B-5B in FIG. 5A.

The semiconductor light emitting device 2 differs from the semiconductor light emitting device 1 according to the above-described embodiment 1 in that the second transparent electrode 32 is formed so as to cover the entire surface of the first transparent electrode 31. The other parts of the configuration are the same as those of the semiconductor light emitting device 1 according to Embodiment 1.

As described above, the sheet resistance of the second transparent electrode 32 is about one fifth of that of the first transparent electrode 31, and the second transparent electrode 32 has higher conductivity than the first transparent electrode 31. By covering the entire surface of the first transparent electrode 31 with the second transparent electrode 32 having low sheet resistance, the resistance of the path for current flowing in a direction parallel to the principal surface of the semiconductor light emitting device can be made lower, thus further reducing the forward voltage. Note that the second transparent electrode 32 need not necessarily cover the entire surface of the first transparent electrode 31, but need only cover a part of the first transparent electrode 31. The first transparent electrode 31 and the second transparent electrode 32 are preferably made thinner than in the semiconductor light emitting device 1 according to Embodiment 1, and for example, the thickness in the overlap of the first transparent electrode 31 and the second transparent electrode 32 can be set at about 110 nm. In view of obtaining higher transparency, it is preferable that the first transparent electrode 31 is thinner than the second transparent electrode 32.

### Embodiment 3

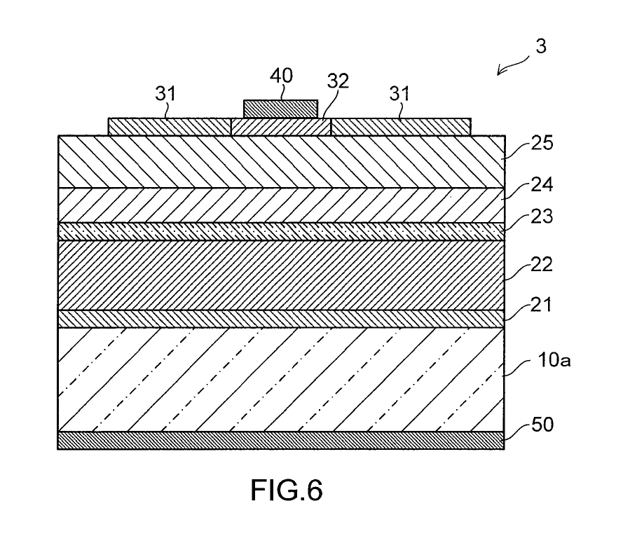

FIG. 6 is a cross-sectional view showing the configuration of a semiconductor light emitting device 3 according to Embodiment 3 of the present invention. The semiconductor light emitting devices according to the above embodiments 1 and 2 are of a so-called face-up type wherein the p-type contact layer 25 and the n-type contact layer 22 are exposed to the same side of the device and the p-side electrode pad 40 and the n-side electrode pad 50 are respectively formed on the exposed surfaces of the p-type contact layer 25 and the n-type contact layer 22. The semiconductor light emitting device 3 according to Embodiment 3 is of a so-called double-side electrode type wherein the p-side electrode pad and the n-side electrode pad are provided so as to sandwich the nitride semiconductor layer and the growth substrate.

The semiconductor light emitting device having double-side electrode structure is applied to the case of performing the crystal growth of the nitride semiconductor layer using a growth substrate 10a having conductivity such as GaN or SiC. A GaN-based nitride semiconductor layer represented by AlₓIn_{y}Ga_{1-x-y}N (0≦x≦1, 0≦y≦1) is formed on the surface of the growth substrate 10a. The nitride semiconductor layer is configured with a buffer layer 21, an n-type contact layer 22, an active layer 23, a p-type clad layer 24, and a p-type contact layer 25 that are laid one over another in that order.

A first transparent electrode 31 made of, e.g., ITO of about 110 nm thickness and a second transparent electrode 32 also made of ITO of about 110 nm thickness are formed on a surface of the p-type contact layer 25. The second transparent electrode 32 is placed on the surface of the p-type contact layer 25, e.g., substantially at the center. The first transparent electrode 31 is formed to surround the second transparent electrode 32 and electrically connected to the second transparent electrode 32. The first transparent electrode 31 and the second transparent electrode 32 are different from each other in contact resistance with the p-type contact layer 25. That is, the contact resistance between the first transparent electrode 31 and the p-type contact layer 25 is, for example, 2×10⁻⁴ Ωcm² to 7×10⁻³ Ωcm², while the contact resistance between the second transparent electrode 32 and the p-type contact layer 25 is, for example, 2×10¹ Ωcm² or greater. The sheet resistance of the first transparent electrode 31 is, for example, 100 to 200Ω/□, while the sheet resistance of the second transparent electrode 32 is, for example, 10 to 40Ω/□.

The p-side electrode pad 40 configured with Ni and Au laid one over the other in that order is formed on the surface of the second transparent electrode 32. The p-side electrode pad 40 comes in contact with only the second transparent electrode 32, not with the first transparent electrode 31. The n-side electrode pad 50 configured with Ti and Al laid one over the other in that order is formed on the back surface, i.e., the surface opposite to the crystal growth surface of the growth substrate 10a having conductivity.

In the semiconductor light emitting device 3 having above mentioned structure, current supplied from the p-side electrode pad 40 flows into the second transparent electrode 32. Because the contact resistances of the first transparent electrode 31 and the second transparent electrode 32 with the p-type contact layer 25 are remarkably different, the current spreads over the entire area of the first transparent electrode 31 having low contact resistance and is injected mainly from the first transparent electrode 31 into the p-type contact layer 25 to flow toward the n-side electrode pad 50. Meanwhile, almost no current is injected from the second transparent electrode 32 having high contact resistance with the p-type contact layer 25 into the p-type contact layer 25. That is, the second transparent electrode 32 diverts the supplied current to the first transparent electrode 31, thus serving as a current control layer that suppresses current concentration immediately beneath the p-side electrode pad 40. The electric current distribution inside the nitride semiconductor layer can be made uniform by appropriately setting the arrangement and areas of the first and second transparent electrodes.

As such, also the semiconductor light emitting device having an electrode configuration where the p-side electrode pad and the n-side electrode pad are placed on opposite sides, sandwiching the nitride semiconductor layer and the growth substrate, can obtain the same effect as the semiconductor light emitting devices according to the embodiments previously described.

In the above embodiments, description has been made taking as an example the case of using ITO as material for the first and second transparent electrodes, but the present invention is not limited to the example. For the first and second transparent electrodes, another metal oxide transparent conductor such as ZTO (zinc tin oxide: Zn₂SnO₄), AZO (aluminum-doped zinc oxide), GZO (gallium-doped zinc oxide), ATO (antimony-doped tin oxide), or FTO (fluorine-doped tin oxide) can also be used Further, in the above embodiments, description has been made taking as an example the case of a semiconductor light emitting device having a GaN-based nitride semiconductor layer, but the present invention can be applied to a semiconductor light emitting device having a GaAs-based semiconductor layer or a GaP-based semiconductor layer.

The present invention has been described above with reference to preferred embodiments thereof. It should be understood that those skilled in the art can think of various modifications and changes and that all variants made by those modifications and changes fall within the scope of the present invention as defined by the appended claims.

This application is based on Japanese Patent Application No. 2010-215194 which is herein incorporated by reference.

What is claimed is:

1. A semiconductor light emitting device which includes an n-type semiconductor layer, a p-type semiconductor layer, and an active layer provided between said n-type semiconductor layer and said p-type semiconductor layer, said semiconductor light emitting device comprising:
a first transparent electrode made of a metal oxide transparent conductor provided on a surface of said p-type semiconductor layer;
a second transparent electrode made of a metal oxide transparent conductor provided on the surface of said p-type semiconductor layer and electrically connected to said first transparent electrode; and
a p-side electrode pad made of metal provided on a surface of said second transparent electrode,
wherein said second transparent electrode is higher in contact resistance with said p-type semiconductor layer than said first transparent electrode.

2. A semiconductor light emitting device according to claim 1, wherein the sheet resistance of said second transparent electrode is lower than the sheet resistance of said first transparent electrode.

3. A semiconductor light emitting device according to claim 1, wherein the band gap of said second transparent electrode is greater than the band gap of said first transparent electrode.

4. A semiconductor light emitting device according to claim 1, wherein the contact resistance of said second transparent electrode with said p-type semiconductor layer is 1,000 times or more greater than the contact resistance of said first transparent electrode with said p-type semiconductor layer.

5. A semiconductor light emitting device according to claim 1, wherein said first and second transparent electrodes are made of tin-doped indium oxide (ITO).

6. A manufacturing method of a semiconductor light emitting device, comprising the steps of:
forming an n-type semiconductor layer, an active layer, and a p-type semiconductor layer on a surface of a growth substrate;
forming a metal oxide transparent conductive film on a surface of said p-type semiconductor layer;
sintering said metal oxide transparent conductive film by heat treatment to form a first transparent electrode;
forming a metal oxide transparent conductive film so as to come in contact with said first transparent electrode on the surface of said p-type semiconductor layer to form a second transparent electrode; and
forming a p-side electrode pad made of metal on a surface of said second transparent electrode.

7. A manufacturing method according to claim 6, wherein said heat treatment is performed in an atmosphere containing oxygen of a temperature at which crystallization of the metal oxide transparent conductive film forming said first transparent electrode is promoted.

8. A manufacturing method according to claim 6, wherein the metal oxide transparent conductive films forming said first and second transparent electrodes are made of tin-doped indium oxide (ITO).

9. A manufacturing method according to claim 8, wherein said heat treatment is performed in an oxygen atmosphere of 500° C. or higher but not higher than 700° C.

10. A manufacturing method according to claim 8, wherein in said steps of forming the metal oxide transparent conductive film, ITO is deposited on the surface of said p-type semiconductor layer by a sputtering method at a substrate temperature of 150° C. or higher but not higher than 300° C.
